(19) United States
(12) Patent Application Publication
(10) Pub. No.: US 2024/0103073 A1
(43) Pub. Date: Mar. 28, 2024

(54) COUPLING A THERMALLY CONDUCTIVE PLATE TO A SEMICONDUCTOR DEVICE FOR ELECTRON BEAM ANALYSIS

(71) Applicant: Intel Corporation, Santa Clara, CA (US)

(72) Inventors: Patrick PARDY, Hillsboro, OR (US); Robert WADELL, Sacramento, CA (US); Tewodros WONDIMU, Hillsboro, OR (US); Michael APODACA, West Roxbury, MA (US); Joshua FREIER, Portland, OR (US); Amir RAVEH, Haifa (IL); Eric BRUMMER, Orangevale, CA (US)

(21) Appl. No.: 17/952,031

(22) Filed: Sep. 23, 2022

(51) Int. Cl. G01R 31/307; H01L 23/467

(52) U.S. Cl. CPC G01R 31/307; H01L 23/467

(57) ABSTRACT

Embodiments described herein may be related to apparatuses, processes, systems, and/or techniques for an enclosure, which may be referred to as a cartridge, that surrounds a semiconductor device prior to the semiconductor device being bombarded with an electron beam during operational testing. In embodiments, the enclosure may include a cooling plate that includes a thermal cooling mechanism that is thermally coupled with the semiconductor device to control the temperature of the semiconductor device during testing. The thermal cooling mechanism may include a manifold that extends through the plate through which a cooled fluid, cooled air, or some other cool material may be circulated to cool the semiconductor device. Other embodiments may be described and/or claimed.

### FIELD

Embodiments of the present disclosure generally relate to the field of semiconductor manufacturing, and in particular to testing for defects on a wafer.

### BACKGROUND

Continued growth in virtual machines, cloud computing, and portable devices will continue to increase the demand for high density transistors within chips and packages. In addition, there will be an increased need for high quality components with an improved efficiency in identifying semiconductor device operation and defects.

### BRIEF DESCRIPTION OF THE DRAWINGS

FIG. 1 illustrates a cross-section side view of a semiconductor device that includes a transistor layer, a front side metal layer, and a back side metal layer, with portions of the front side metal layer and the back side metal layer removed and areas of the transistor layer exposed to electron beams, in accordance with various embodiments.

FIG. 2 illustrates a cross section side view of a system for exposing an electron beam to a front side of a semiconductor device, where the semiconductor device is thermally coupled to a cooling plate, in accordance with various embodiments.

FIG. 3 is an exploded view of an enclosure for a semiconductor device that is to be exposed to an electron beam on the front side of the semiconductor device, in accordance with various embodiments.

FIG. 4 illustrates a cross section side view of a system for exposing an electron beam to a back side of a semiconductor device, where the semiconductor device is thermally coupled to a cooling plate, in accordance with various embodiments.

FIG. 5 is an exploded view of an enclosure for a semiconductor device that is exposed to an electron beam on the back side of the semiconductor device, in accordance with various embodiments.

FIG. 6 illustrates the cross section side view of an enclosure for a semiconductor device that is exposed to an electron beam on the back side of the semiconductor device, in accordance with various embodiments.

FIG. 7 illustrates a cross section side view of a system for exposing an electron beam to a semiconductor device, in accordance with various embodiments.

FIG. 8 illustrates an example process for coupling a thermally conductive plate to a semiconductor device for electron beam analysis, in accordance with various embodiments.

FIG. 9 illustrates a computing device in accordance with one implementation of the invention.

FIG. 10 illustrates an interposer that includes one or more embodiments of the invention.

### DETAILED DESCRIPTION

Embodiments described herein may be related to apparatuses, processes, systems, and/or techniques for providing an enclosure, which may be referred to as a cartridge, that surrounds a semiconductor device prior to the semiconductor device being bombarded with an electron beam during operational testing. These electron-beam techniques may be used to detect and produce waveforms, change electrical edges, obtain the frequency of a node or find static based process faults within circuitry of the semiconductor device. In embodiments, the enclosure may serve as a clamp to secure the semiconductor device, as well as to facilitate vacuum as the semiconductor device is being bombarded with the electron beam. Other techniques described herein may be directed to vacuum proof environments where a semiconductor device is fully isolated from the outside world and provides for vacuum levels that enable proper operation of an electron-beam system.

In embodiments, the enclosure may include a cooling plate that includes a thermal cooling mechanism, where the cooling plate is thermally coupled with the semiconductor device to control the temperature of the semiconductor device during testing or looping. In embodiments, the thermal cooling mechanism may include a manifold that extends through the plate through which a cooled fluid, cooled air, or some other cooling material may be circulated to cool the semiconductor device. In embodiments, the cooling plate may include copper, silver, aluminum, graphene, gold, and/or brass, or other materials, and include input and output ports for circulation of material.

In embodiments, a backing plate may be coupled with the cooling plate, where the semiconductor device is between the cooling plate and the backing plate. In embodiments, a drill may be used to drill a hole in the cooling plate or the backing plate, where the hole may extend through to and into the semiconductor device. In embodiments, the drill may also remove a portion of the semiconductor device, for example, a metal or interlayer dielectric layer of the semiconductor device, to expose a portion of the transistor layer or another metal layer to be bombarded by the electron beam. In embodiments, the semiconductor device between the cooling plate and the backing plate, as well as the volume between the source of the electronic beam may be under a vacuum.

An electron beam may then be generated, and the generated electrons accelerated and sent into the hole, incident to a surface of interest. Secondary electrons are repelled off the exposed metal or transistor surface of interest and analyzed through use of detectors. For example, the repelled secondary electrons may have different energy levels based upon the current operational state of the exposed portion of the transistor or metal layer. The secondary electron beam may then be analyzed to determine operational characteristics, for example timing, of circuitry at the exposed portion of the transistor or metal interconnect layer. In embodiments, the cooling plate, the semiconductor device, and the backing plate may be in a cartridge-like configuration that may be inserted into a testing system that uses an electron beam device for semiconductor device analysis. In embodiments, the manifold within the cooling plate may have a configuration such that the hole drilled within the cooling plate will avoid intersecting any of the portions of the manifold. In embodiments, there may be markings on a surface of the cooling plate to indicate areas into which holes may be safely drilled. In embodiments the system may incorporate a thermally conductive plate, vibration isolation, electron beam access hole and method for vacuum sealing of a semiconductor device during test.

In legacy implementations, photonics-based processes, using light, are used to inject light to a semiconductor device, which will then penetrate silicon layers and affect circuitry, such as transistor circuitry, to effect changes that can be used to assess the quality and operational characteristics of the semiconductor device. For example, these legacy techniques may be used to artificially move electrical edges on the circuitry, obtain electro-optical-based waveforms, and/or map frequency of nodes of the circuitry. These legacy techniques rely on the light being injected into the transistors. However, given the implementation of multiple metal layers, for example in front side metal layer and a back side metal layer surrounding a transistor layer of the semiconductor device, these techniques using light-based technologies, are unable to penetrate the metal layers to effect changes in the transistor layer.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

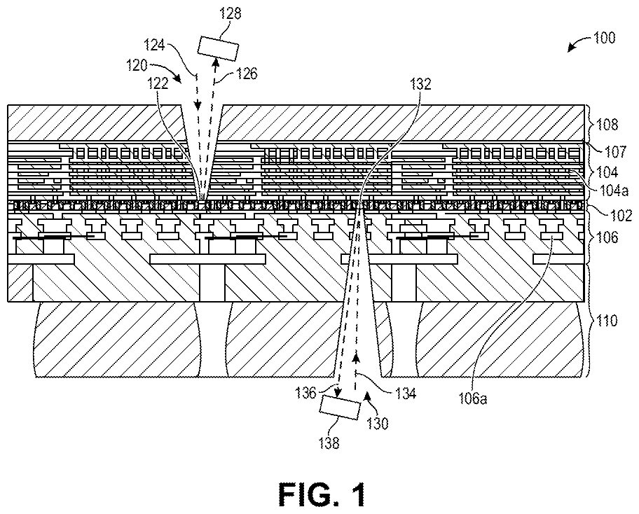

FIG. 1 illustrates a cross-section side view of a semiconductor device that includes a transistor layer, one or more front side metal layers and one or more back side metal layers, with portions of the front side metal layer and the back side metal layer removed and areas of the transistor layer exposed to electron beams, in accordance with various embodiments. Semiconductor device 100 illustrates a cross-section side view that includes a transistor layer 102. On one side of the transistor layer 102 there is a front side interconnect layer 104 that may include metal layers 104a that may be used to provide electrical routing with various components within the transistor layer 102. On the other side of the transistor layer 102, opposite the front side interconnect layer 104, there is a back side interconnect layer 106 that may include metal layers 106a that may be used to provide electrical routing to various components within the transistor layer 102 and with a package 110 may be physically coupled with the back side interconnect layer 106. A carrier wafer 108, which may include silicon or may be bulk silicon, may be physically coupled with the front side interconnect layer 104, and may be used to support the semiconductor device 100 during handling while the semiconductor device 100 is undergoing testing. In embodiments, an epoxy layer 107 may couple the front side interconnect layer 104 with the carrier wafer 108.

In embodiments, a front side cavity 120, which may be referred to as a hole or a front side hole, may be created through the front side interconnect layer 104 and carrier wafer 108, to expose a portion 122 of the transistor layer 102. In embodiments, the front side cavity 120 may be created through a drilling process. Subsequently, an electron beam 124 may be shown into front side cavity 120 and incident on the portion 122 of the transistor layer 102 and repelled secondary electrons 126. The repelled secondary electrons 126 may then be detected by a detector 128. The characteristics of the repelled secondary electrons 126, for example a pattern of the repelled secondary electrons 126, may indicate operational characteristics of the semiconductor device 100 under electrical test.

In embodiments, the electron beam 124 may also be used on one or more of the metal layers 104a, or metal layers 106a, where secondary electrons may also be repelled depending on the electrical signal that may be traveling through the one or more metal layers 104a or metal layers 106a.

Similarly, in embodiments, a back side cavity 130, which may be referred to as a hole or a back side hole, may be created through the package 110 and the back side interconnect layer 106, to expose a portion 132 of the transistor layer 102. In embodiments, the back side cavity 130 may be created through a drilling process. Subsequently, an electron beam 134 may be incident into back side cavity 130 and repelled secondary electrons off the portion 132 of the transistor layer 102 as repelled secondary electrons 136. The repelled secondary electrons 136 may then be detected by a detector 138. The characteristics of the repelled secondary electrons 136 may indicate operational characteristics of the semiconductor device 100 under electrical test.

In embodiments, the front side cavity 120 or the back side cavity 130 may be dimensioned based on characteristics of the electron beam 124 or electron beam 134, and the desired characteristics of the repelled secondary electrons 126 or the repelled secondary electrons 136. This may include various aspect ratios, widths, geometry of the sides, and the like of the front side cavity 120 or the back side cavity 130. In embodiments, the dimensions may be used to minimize beam shift. In embodiments, the dimensions may be based upon a repelled secondary electron pattern off of the semiconductor device 100. In embodiments, the dimensions may be optimized for transistor or metal layer imaging and may be optimized for repelled secondary electron yield for best detection.

In embodiments, the detectors 128, 138 may be used to collect repelled secondary electrons, and then analyze the operation of the semiconductor device 100 based on the collected repelled secondary electrons. In embodiments, this may be done while the semiconductor device 100 is in operation.

In embodiments, these techniques with respect to semiconductor device 100 may also be applied to other devices, including wirebonded semiconductor devices, controlled collapse chip connection (C4) flip chip semiconductor devices, three-dimensional integrated circuit semiconductor devices, or other types of semiconductor devices.

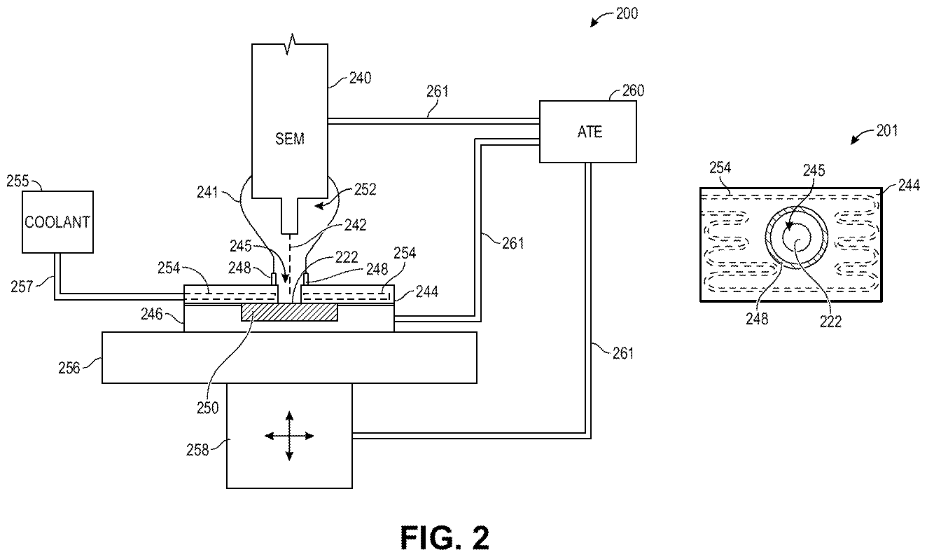

FIG. 2 illustrates a cross section side view of a system for exposing an electron beam to a front side of a semiconductor device, where the semiconductor device is thermally coupled to a cooling plate, in accordance with various embodiments. System 200 shows a scanning electron microscope (SEM) 240 that is used to generate an electron beam 242, which may be similar to electron beam 124 of FIG. 1. A semiconductor device 250, which may be similar to semiconductor device 100 of FIG. 1, may be thermally coupled with a cooling plate 244 and may be at least partially between the cooling plate 244 and a backing plate 246. In embodiments, the cooling plate 244 may include copper, silver, aluminum, graphene, gold, and/or brass, or may include some other thermally conductive element. In embodiments, the cooling plate 244 and the backing plate 246 may be coupled with each other, such that there is an airtight coupling between the cooling plate 244 and the backing plate 246.

In embodiments, the cooling plate 244 may have a hole 245 drilled through the cooling plate 244 to expose at least a portion 222 of the semiconductor device 250. Portion 222 of the semiconductor device 250 may be similar to portion 122 of the semiconductor device 100 of FIG. 1. In embodiments, a gasket 248 may be on the top of the cooling plate 244, which may seal with a housing 241 that allows a vacuum to be formed within area 252, so that at least the electron beam 242, the hole 245, and the portion 222 of the semiconductor device 250 are subject to a vacuum during operation. In embodiments, the gasket 248 may be an O-ring.

In embodiments, the cooling plate 244 may include a manifold 254, which may include piping, within the cooling plate 244. In embodiments, coolant may be provided from a coolant source 255 through coolant delivery mechanism 257 to the manifold 254. In embodiments, a layout of the manifold 254 may be designed to avoid any holes 245 that may need to be drilled through the cooling plate 244. In embodiments, an input port (not shown) and an output port (not shown) may be coupled with the coolant delivery mechanism 257 and with the manifold 254. In embodiments, the coolant delivery mechanism 257 and the cooling plate 244 may be referred to as part of a cooling system.

In embodiments, the cooling plate 244, the backing plate 246, and the semiconductor device 250 may be on a platform 256. In embodiments, the platform 256 may be on a stage 258, where the stage 258 may move in an X, Y, and/or Z direction. In embodiments, the stage 258 may be lowered while the cooling plate 244 with the gasket 248, the backing plate 246, and the semiconductor device 250 are placed as a unit on the platform 256. The stage 258 may then be raised, allowing the gasket 248 to dock and seal itself to the housing 241 prior to any testing.

In embodiments, testing equipment, which may be referred to as automated test equipment (ATE) 260 may be electrically coupled, using electrical connections 261, with the SEM 240, the backing plate 246, and the stage 258. In embodiments, the semiconductor device 250 may be coupled with the ATE 260 through a socket (not shown) in the backing plate 246. In embodiments, the socket (not shown) may include one or more electrical connectors. In embodiments, the ATE 260 may control the location and strength of the electron beam 242, may operate the semiconductor device 250, may adjust the stage 258, and may detect any repelled secondary electrons from a detector (not shown, but may be similar to repelled secondary electrons 126 and detector 128 of FIG. 1).

Diagram 201 shows a top-down cross-section view of the cooling plate 244, that includes the manifold 254, gasket 248, hole 245, and portion 222 of semiconductor device 250.

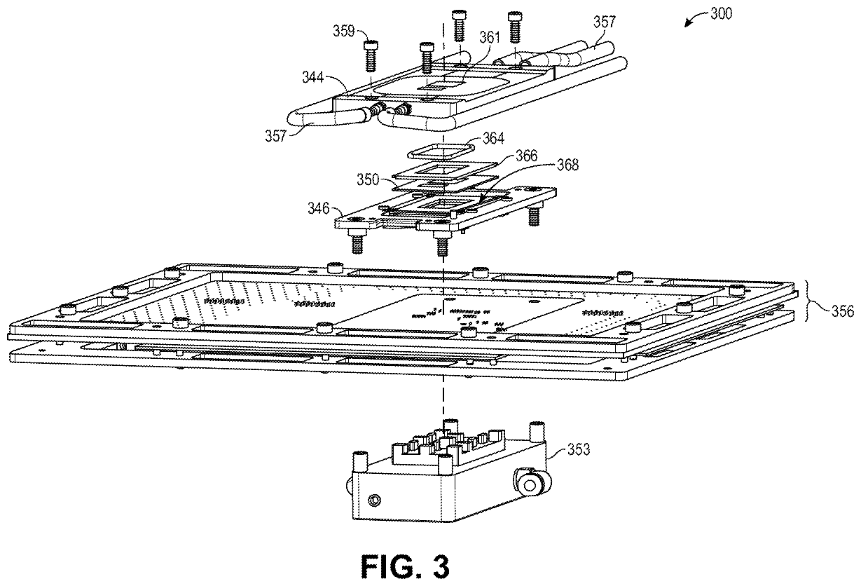

FIG. 3 is an exploded view of an enclosure for a semiconductor device that is to be exposed to an electron beam on the front side of the semiconductor device, in accordance with various embodiments. Diagram 300 shows an embodiment that includes a cooling plate 344, a backing plate 346, and a semiconductor device 350, which may be similar to cooling plate 244, backing plate 246, and semiconductor device 250 of FIG. 2. Diagram 300 shows additional components that may be included between and/or surrounding the cooling plate 344 and the backing plate 346.

In embodiments, there may be multiple coolant delivery mechanism 357, which may be similar to coolant delivery mechanism 257 of FIG. 2. Fasteners 359 may be used to secure the cooling plate 344 to the backing plate 346. In embodiments, markings 361 may be made on top of the cooling plate 344 to indicate where holes, such as holes 245 of FIG. 2, may be drilled to expose portions of the semiconductor device 350 and avoid intersecting a manifold (not shown but similar to manifold 254 of FIG. 2). In embodiments, the markings 361 may be used to indicate a layout of one or more areas of the semiconductor device 350. In embodiments, between the semiconductor device 350 and the cooling plate 344 there may be a gasket 364 and a stiffener 366.

In embodiments, a socket 368 may be within the backing plate 346, onto which the semiconductor device 350 may electrically couple. In embodiments, the backing plate 346 may be electrically and/or physically coupled with the semiconductor circuit test card 356, which may be similar to platform 256 of FIG. 2, by one or more electrical connectors (not shown). In embodiments, the semiconductor circuit test card 356 may be connected to a platform test interface unit (not shown). In embodiments, a stiffener 353 may be coupled with the semiconductor circuit test card 356 in order to provide additional rigidity to the semiconductor circuit test card 356.

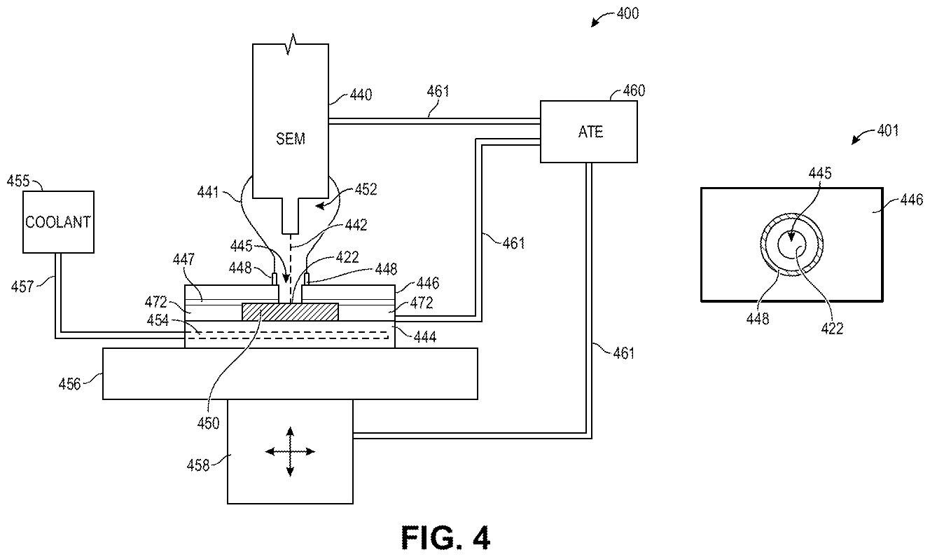

FIG. 4 illustrates a cross section side view of a system for exposing an electron beam to a back side of a semiconductor device, where the semiconductor device is thermally coupled to a cooling plate, in accordance with various embodiments. System 400 shows a SEM 440, which may be similar to SEM 240 of FIG. 2, that is used to generate an electron beam 442, which may be similar to electron beam 134 of FIG. 1. A semiconductor device 450, which may be similar to semiconductor device 100 of FIG. 1, may be thermally coupled with a cooling plate 444 and may be at least partially between the cooling plate 444 and a backing plate 446.

In embodiments, the cooling plate 444 and the backing plate 446 may be coupled with each other, such that there is an airtight coupling between the cooling plate 444 and the backing plate 446. In embodiments, there may be a test interface unit 447 that may electrically couple with the semiconductor device 450 and may be used to operate the semiconductor device 450 during tests, between the cooling plate 444 in the backing plate 446. In embodiments, a press plate 472 may surround the semiconductor device 450 and may be between the cooling plate 444 and the backing plate 446.

In embodiments, the backing plate 446 may have a hole 445 drilled through the backing plate 446 to expose at least a portion 422 of the semiconductor device 450. In embodiments, the hole 445 may be proximate to at least a portion 422 of the semiconductor device 450, and embodiments the portion 422 of the semiconductor device will be aligned with the SEM 440 such that the electron beam 442 is able to intersect the portion 422 of the semiconductor device 450.

In embodiments, portion 422 of the semiconductor device 450 may be similar to portion 132 of the semiconductor device 100 of FIG. 1. In embodiments, a gasket 448 may be on the top of the backing plate 446, which may seal with a housing 441 that allows a vacuum or a partial vacuum to be formed within area 452, so that at least the electron beam 442, the hole 445, and the portion 422 of the semiconductor device 450 are subject to a vacuum.

In embodiments, the cooling plate 444 may include a manifold 454, which may include piping, within the cooling plate 444. In embodiments, coolant may be provided from a coolant source 455 through coolant delivery mechanism 457 to the manifold 454. In embodiments, an input port (not shown) and an output port (not shown) may be coupled with the coolant delivery mechanism 457 and with the manifold 454. In embodiments, the coolant delivery mechanism 457 and the cooling plate 444 may be referred to as part of a cooling system.

In embodiments, the cooling plate 444, the backing plate 446, and the semiconductor device 450 may be on a platform 456, which may be similar to platform 256 of FIG. 2. In embodiments, the platform 456 may be on a stage 458, where the stage 458 may move in an X, Y, and/or Z direction. In embodiments, the stage 458 may be lowered while the cooling plate 444 the backing plate 446 with gasket 448, and the semiconductor device 450 are placed on the platform 456. The stage 458 may then be raised, allowing the gasket 448 to dock and seal itself to the housing 441 prior to any testing.

In embodiments, ATE 460 may be electrically coupled using electrical connections 461 with the SEM 440, the test interface unit 447, and the stage 458. In embodiments, the semiconductor device 450 may be coupled with the ATE 460 through the test interface unit 447. In embodiments, the ATE 460 may control the location and strength of the electron beam 442, operation of the semiconductor device 450, adjust the stage 458, and detect any repelled secondary electrons from a detector (not shown, but may be similar to repelled secondary electrons 136 and detector 138 of FIG. 1).

Diagram 401 shows a top-down cross-section view of the backing plate 446, that includes the gasket 448, hole 445, and portion 422 of semiconductor device 450.

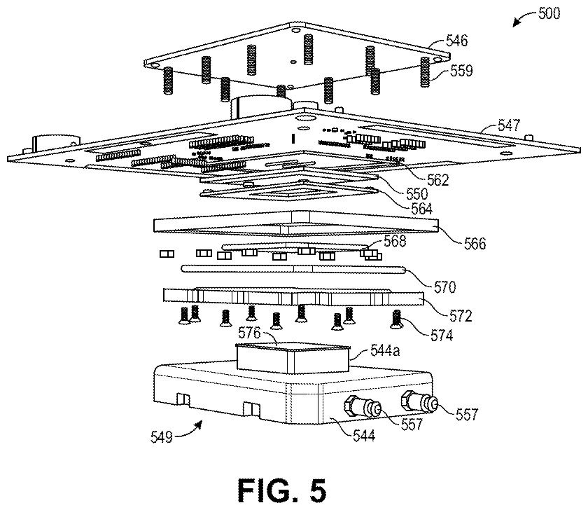

FIG. 5 is an exploded view of an enclosure for a semiconductor device that is exposed to an electron beam on the back side of the semiconductor device, in accordance with various embodiments. Diagram 500 shows an embodiment of detail for a cooling plate 544, a backing plate 546, test interface unit 547, and a semiconductor device 550, which may be similar to cooling plate 444, backing plate 446, test interface unit 447, and semiconductor device 450 of FIG. 4. Diagram 500 shows additional components that may be included between and/or surrounding the cooling plate 544 and the backing plate 546.

In embodiments, there may be multiple coolant delivery mechanisms 557, which may be similar to coolant delivery mechanism 457 of FIG. 4, for cooling plate 544. Fasteners 559 may be used to secure the backing plate 546 to the cooling plate 544. In embodiments, between the semiconductor device 550 and test interface unit 547 there may be an elastomer socket 562 to facilitate electrical coupling between the semiconductor device 550 and the test interface unit 547.

In embodiments, a package stiffener 564 may be coupled with the semiconductor device 550. In embodiments, a top plate 566 may be coupled with the test interface unit 547. One or more o-rings 568, 570 may separate the top plate 566 from a press plate 572, which may be coupled using one or more fasteners 574. In embodiments, a raised portion 544a of the cooling plate 544 may come into thermal contact with the semiconductor device 550. In embodiments, a thermal interface material (TIM) 576 may be on top of the raised portion 544a. In embodiments, an epoxy 549 may be on the bottom of the cooling plate 544, where the epoxy 549 may provide a seal to facilitate a smooth surface and vacuum seal during testing.

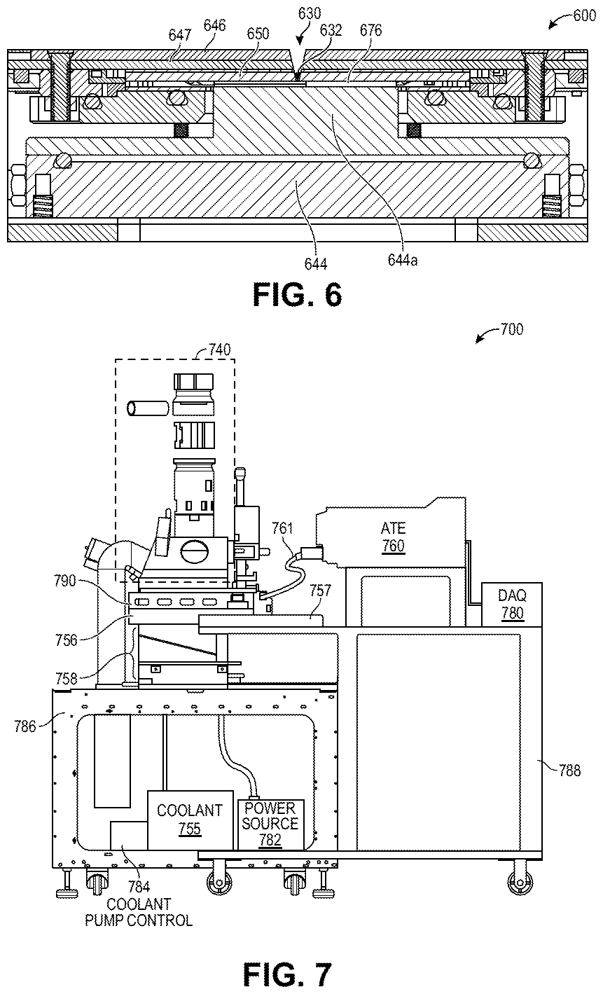

FIG. 6 illustrates the cross section side view of an enclosure for a semiconductor device that is exposed to an electron beam on the back side of the semiconductor device, in accordance with various embodiments. Diagram 600, which may be similar to diagram 500 of FIG. 5, shows a backing plate 646 that is above a test interface unit 647, which may be similar to backing plate 546 and test interface unit 547 of FIG. 5. In embodiments, a socket (not shown but may be similar to elastomer socket 562 of FIG. 5), may be electrically coupled with the test interface unit 647 and the semiconductor device 650, which may be similar to semiconductor device 550 of FIG. 5.

In embodiments, a hole 630, which may be similar to back side cavity 130 of FIG. 1, may expose a portion 632 of the semiconductor device 650, which may be similar to portion 132 of the semiconductor device 100 of FIG. 1. In embodiments, the hole 630 may be a cone shaped hole that is formed using a drill process. In embodiments, a cooling plate 644 with a raised portion 644a, which may be similar to cooling plate 544 and raised portion 544a of FIG. 5, may be thermally coupled with the semiconductor device 650. In embodiments, a TIM 676, which may be similar to TIM 576 of FIG. 5, may thermally couple the cooling plate 644 with the semiconductor device 650.

FIG. 7 illustrates a cross section side view of a system for exposing an electron beam to a semiconductor device, in accordance with various embodiments. System 700, which may also be referred to as a testing environment, may include a SEM 740, which may be similar to SEM 240 of FIG. 2 or SEM 440 of FIG. 4. In embodiments, the SEM 740 may include a housing at the bottom, that may be similar to housing 241 of FIG. 2 or housing 441 of FIG. 4, that may be used to form a vacuum seal.

In embodiments, a cartridge 790, may include a backing plate, semiconductor device, and cooling plate similar to cooling plate 244, semiconductor device 250, and backing plate 246 of FIG. 2, cooling plate 444, semiconductor device 450, and backing plate 446 of FIG. 4, or cooling plate 644, semiconductor device 650, and backing plate 646 of FIG. 6. In embodiments, the cartridge 790 may fit in directly below the SEM 740 and form a vacuum seal. In embodiments, the cartridge 790 may be coupled with another vacuum device (not shown) in order to test the quality of a vacuum seal that may be formed within the cartridge 790 and any associated sealing surfaces, or to test for any outgassing leaks.

In embodiments, the cartridge 790 may be on a platform 756, which may be similar to platform 256 of FIG. 2, or platform 456 of FIG. 4. In embodiments, the platform 756 may move on a slide 757 to move the cartridge 790 in or out from under the SEM 740. In embodiments, the platform 756 may be on a stage 758, which may be similar to stage 258 of FIG. 2, or stage 458 of FIG. 4. In embodiments, the stage 758 may be able to move in the X, Y, and/or Z directions to facilitate proper alignment of the cartridge 790 with respect to the SEM 740. In embodiments, the stage 758 may include hydraulic lifts to facilitate movement in a Z direction.

In embodiments, the SEM 740, cartridge 790, platform 756, and stage 758 may be on a table 786. In embodiments, a surface of the table 786 may include a metal or other heavy material, such as a stone or a granite, to facilitate stability and minimize vibration experienced by the SEM 740 during testing. In embodiments, a power source 782 may provide electrical power to the system 700. In embodiments, a coolant source 755, which may be similar to coolant source 255 of FIG. 2, or coolant source 455 of FIG. 4. In embodiments, a chiller and/or coolant pump 784 may be coupled with the coolant source 755 to maintain a constant temperature of the coolant, and to provide adequate cooling to the cartridge 790.

In embodiments, an ATE 760, which may be similar to ATE 260 of FIG. 2, or ATE 460 of FIG. 4, may be electrically coupled with the various components of the system 700 using electrical connection 761, which may be similar to electrical connections 261 of FIG. 2 or electrical connections 461 of FIG. 4. In embodiments, a material or a length of the electrical connection 761 may be chosen to minimize vibration between the ATE 760 and other components of the system 700. In embodiments, the electrical connection 761 may include cabling that carries both power and signals. In embodiments, cabling may minimize vibration, allowing for clearer nanometer-scale imaging. In embodiments, a data acquisition unit (DAQ) 780 may be electrically coupled with the ATE 760 to record the results of tests that may be performed. In embodiments, the ATE 760 and DAQ 780 may be on a separate table 788 to minimize vibration among the components of system 700.

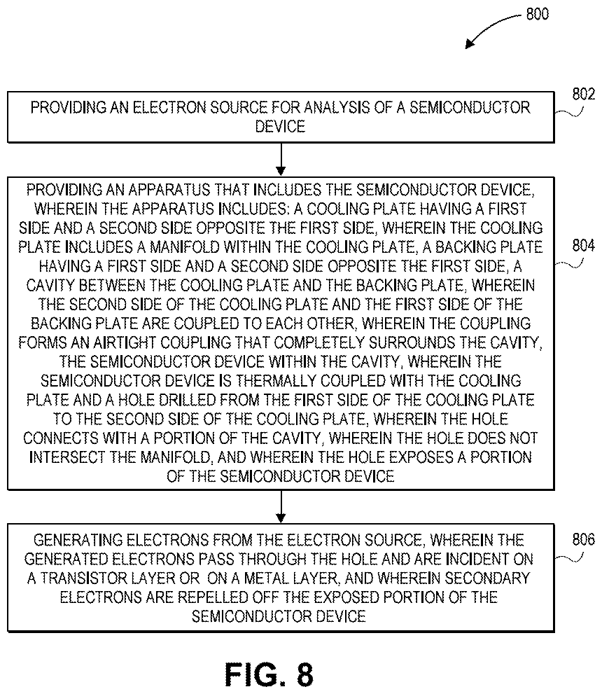

FIG. 8 illustrates an example process for coupling a thermally conductive plate to a semiconductor device for electron beam analysis, in accordance with various embodiments. Process 800 may be performed using the systems, apparatus, processes, and/or techniques described herein, and in particular with respect to FIGS. 1-7.

At block 802, the process may include providing an electron source for analysis of a semiconductor device.

At block 804, the process may further include providing an apparatus that includes the semiconductor device, wherein the apparatus includes: a cooling plate having a first side and a second side opposite the first side, wherein the cooling plate includes a manifold within the cooling plate, a backing plate having a first side and a second side opposite the first side, a cavity between the cooling plate and the backing plate, wherein the second side of the cooling plate and the first side of the backing plate are coupled to each other, wherein the coupling forms an airtight coupling that completely surrounds the cavity, the semiconductor device within the cavity, wherein the semiconductor device is thermally coupled with the cooling plate and a hole drilled from the first side of the cooling plate to the second side of the cooling plate, wherein the hole connects with a portion of the cavity, wherein the hole does not intersect the manifold, and wherein the hole exposes a portion of the semiconductor device.

At block 806, the process may further include generating electrons from the electron source, wherein the generated electrons pass through the hole and are incident on a transistor layer or on a metal layer, and wherein secondary electrons are repelled off the exposed portion of the semiconductor device.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

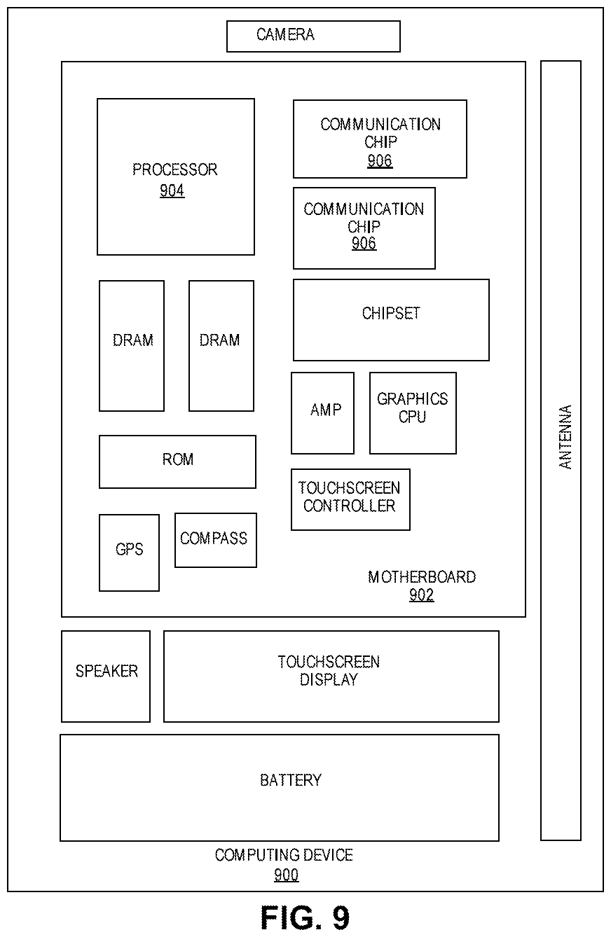

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip includes one or more devices, such as MOS-FET transistors built in accordance with implementations of the invention.

In further implementations, another component housed within the computing device 900 may contain an integrated circuit die that includes one or more devices, such as MOS-FET transistors built in accordance with implementations of the invention.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

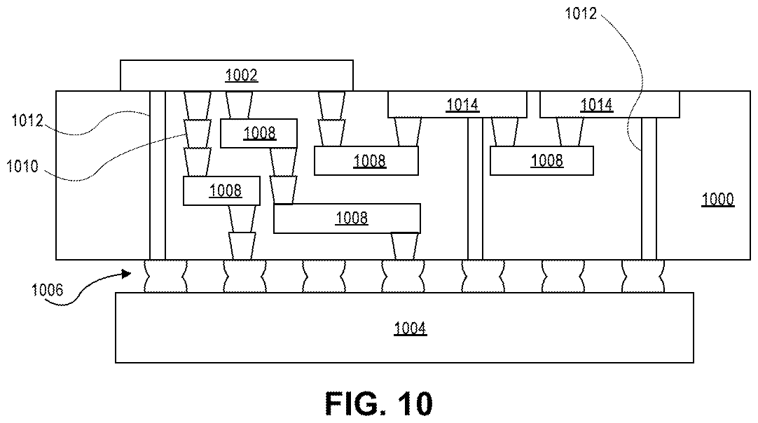

FIG. 10 illustrates an interposer 1000 that includes one or more embodiments of the invention. The interposer 1000 is an intervening substrate used to bridge a first substrate 1002 to a second substrate 1004. The first substrate 1002 may be, for instance, an integrated circuit die. The second substrate 1004 may be, for instance, a memory module, a computer motherboard, or another integrated circuit die. Generally, the purpose of an interposer 1000 is to spread a connection to a wider pitch or to reroute a connection to a different connection. For example, an interposer 1000 may couple an integrated circuit die to a ball grid array (BGA) 1006 that can subsequently be coupled to the second substrate 1004. In some embodiments, the first and second substrates 1002/1004 are attached to opposing sides of the interposer 1000. In other embodiments, the first and second substrates 1002/1004 are attached to the same side of the interposer 1000. And in further embodiments, three or more substrates are interconnected by way of the interposer 1000.

The interposer 1000 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer 1000 may include metal interconnects 1008 and vias 1010, including but not limited to through-silicon vias (TSVs) 1012. The interposer 1000 may further include embedded devices 1014, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1000. In accordance with embodiments of the invention, apparatuses or processes disclosed herein may be used in the fabrication of interposer 1000.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is an apparatus comprising: a cooling plate having a first side and a second side opposite the first side; a backing plate having a first side and a second side opposite the first side; a cavity between the cooling plate and the backing plate, wherein the second side of the cooling plate and the first side of the backing plate are coupled to each other, wherein the coupling forms an airtight coupling that completely surrounds the cavity; and a manifold within the cooling plate.

Example 2 includes the apparatus of example 1, further comprising a hole drilled from the first side of the cooling plate to the second side of the cooling plate, wherein the hole connects with a portion of the cavity, and wherein the hole does not intersect the manifold.

Example 3 includes the apparatus of example 2, further comprising a gasket on the first side of the cooling plate, wherein the gasket surrounds the hole.

Example 4 includes the apparatus of examples 1, 2, or 3, further comprising a semiconductor device within the cavity, wherein the semiconductor device is thermally coupled with the cooling plate.

Example 5 includes the apparatus of example 4, wherein the semiconductor device is coupled with the first side of the backing plate.

Example 6 includes the apparatus of examples 4 or 5, wherein the semiconductor device is electrically coupled with a socket on the first side of the backing plate.

Example 7 includes the apparatus of examples 4, 5, or 6, wherein the second side of the backing plate includes one or more electrical connectors that are electrically coupled with the semiconductor device.

Example 8 includes the apparatus of examples 4, 5, 6, or 7, further comprising a spacer between the semiconductor device and the second side of the cooling plate.

Example 9 includes the apparatus of examples 1, 2, 3, 4, 5, 6, 7, or 8, wherein the cooling plate further comprises an input port and an output port coupled with the manifold.

Example 10 includes the apparatus of examples 1, 2, 3, 4, 5, 6, 7, 8 or 9, wherein the first side of the cooling plate include markings that are related to a layout of one or more areas of a semiconductor device.

Example 11 includes the apparatus of examples 1, 2, 3, 4, 5, 6, 7, 8, 9, or 10, wherein the cooling plate includes a selected one or more of: copper, silver, aluminum, graphene, gold, or brass.

Example 12 is an apparatus comprising: a cooling plate having a first side and a second side opposite the first side; a backing plate having a first side and a second side opposite the first side; a manifold within the backing plate; a semiconductor device between the cooling plate and the backing plate, wherein the semiconductor device is electrically coupled with a socket, and wherein the semiconductor device is thermally coupled with the backing plate; a hole within the cooling plate that extends from a first side of the cooling plate to a second side of the cooling plate opposite the first side, wherein the hole is proximate to a location of the semiconductor device; and wherein the cooling plate and the backing plate are coupled with each other, wherein the coupling forms an airtight coupling that completely surrounds the semiconductor device.

Example 13 includes the apparatus of example 12, wherein the socket is a portion of a board, and wherein the socket is between the cooling plate and the backing plate.

Example 14 includes the apparatus of examples 12 or 13, wherein the backing plate further comprises an input port and an output port that are coupled with the manifold.

Example 15 includes the apparatus of examples 12, 13 or 14, wherein the backing plate includes selected one or more of: copper, silver, aluminum, graphene, gold, or brass.

Example 16 includes the apparatus of examples 12, 13, 14, or 15, further comprising an epoxy coupled with a side of the backing plate.

Example 17 includes the apparatus of examples 12, 13, 14, 15, or 16, wherein the hole is dimensioned based upon a pattern of repelled electrons off the location of the semiconductor device.

Example 18 is a system comprising: an electron source; an apparatus that includes a semiconductor device, wherein the apparatus includes: a cooling plate having a first side and a second side opposite the first side, wherein the cooling plate includes a manifold within the cooling plate; a backing plate having a first side and a second side opposite the first side; a cavity between the cooling plate and the backing plate, wherein the second side of the cooling plate and the first side of the backing plate are coupled to each other, wherein the coupling is an airtight coupling that completely surrounds the cavity, wherein the semiconductor device is within the cavity, and wherein the semiconductor device is thermally coupled with the cooling plate; and a hole drilled from the first side of the cooling plate to the second side of the cooling plate, wherein the hole connects with a portion of the cavity, wherein the hole does not intersect the manifold, and wherein the hole exposes a portion of the semiconductor device; and wherein the exposed portion of the semiconductor device and the electron source are aligned.

Example 19 includes the system of example 18, wherein at least a portion of the electron source, the hole, and the portion of the semiconductor device are under at least a partial vacuum.

Example 20 includes the system of examples 18 or 19, further comprising a platform coupled to the apparatus, wherein the platform is configured to adjust the apparatus with respect to a location of the electron source.

Example 21 includes the system of examples 18, 19, or 20, further comprising automated test equipment (ATE), wherein the ATE is coupled with the electron source or the apparatus.

Example 22 includes the system of example 21, wherein the ATE is coupled with the electron source or the apparatus using cabling.

Example 23 includes the system of examples 18, 19, 20, 21 or 22, further comprising a cooling system, wherein the cooling system is thermally coupled with the manifold.

Example 24 is a method comprising: providing an electron source for analysis of a semiconductor device; providing an apparatus that includes the semiconductor device, wherein the apparatus includes: a cooling plate having a first side and a second side opposite the first side, wherein the cooling plate includes a manifold within the cooling plate; a backing plate having a first side and a second side opposite the first side; a cavity between the cooling plate and the backing plate, wherein the second side of the cooling plate and the first side of the backing plate are coupled to each other, wherein the coupling forms an airtight coupling that completely surrounds the cavity, wherein the semiconductor device is within the cavity, and wherein the semiconductor device is thermally coupled with the cooling plate; and a hole drilled from the first side of the cooling plate to the second side of the cooling plate, wherein the hole connects with a portion of the cavity, wherein the hole does not intersect the manifold, and wherein the hole exposes a portion of the semiconductor device; and generating electrons from the electron source, wherein the generated electrons pass through the hole and are incident on a transistor layer or on a metal layer, and wherein secondary electrons are repelled off the exposed portion of the semiconductor device.

Example 25 includes the method of example 24, further comprising: operating the semiconductor device; collecting the repelled secondary electrons; and analyzing an operation of the semiconductor device based on the collected repelled secondary electrons.

What is claimed:

1. An apparatus comprising:
a cooling plate having a first side and a second side opposite the first side;
a backing plate having a first side and a second side opposite the first side;
a cavity between the cooling plate and the backing plate, wherein the second side of the cooling plate and the first side of the backing plate are coupled to each other, wherein the coupling forms an airtight coupling that completely surrounds the cavity; and
a manifold within the cooling plate.

2. The apparatus of claim 1, further comprising a hole drilled from the first side of the cooling plate to the second side of the cooling plate, wherein the hole connects with a portion of the cavity, and wherein the hole does not intersect the manifold.

3. The apparatus of claim 2, further comprising a gasket on the first side of the cooling plate, wherein the gasket surrounds the hole.

4. The apparatus of claim 1, further comprising a semiconductor device within the cavity, wherein the semiconductor device is thermally coupled with the cooling plate.

5. The apparatus of claim 4, wherein the semiconductor device is coupled with the first side of the backing plate.

6. The apparatus of claim 5, wherein the semiconductor device is electrically coupled with a socket on the first side of the backing plate.

7. The apparatus of claim 5, wherein the second side of the backing plate includes one or more electrical connectors that are electrically coupled with the semiconductor device.

8. The apparatus of claim 4, further comprising a spacer between the semiconductor device and the second side of the cooling plate.

9. The apparatus of claim 1, wherein the cooling plate further comprises an input port and an output port coupled with the manifold.

10. The apparatus of claim 1, wherein the first side of the cooling plate include markings that are related to a layout of one or more areas of a semiconductor device.

11. The apparatus of claim 1, wherein the cooling plate includes a selected one or more of: copper, silver, aluminum, graphene, gold, or brass.

12. An apparatus comprising:
a cooling plate having a first side and a second side opposite the first side;
a backing plate having a first side and a second side opposite the first side;
a manifold within the backing plate;
a semiconductor device between the cooling plate and the backing plate, wherein the semiconductor device is electrically coupled with a socket, and wherein the semiconductor device is thermally coupled with the backing plate;
a hole within the cooling plate that extends from a first side of the cooling plate to a second side of the cooling plate opposite the first side, wherein the hole is proximate to a location of the semiconductor device; and
wherein the cooling plate and the backing plate are coupled with each other, wherein the coupling forms an airtight coupling that completely surrounds the semiconductor device.

13. The apparatus of claim 12, wherein the socket is a portion of a board, and wherein the socket is between the cooling plate and the backing plate.

14. The apparatus of claim 12, wherein the backing plate further comprises an input port and an output port that are coupled with the manifold.

15. The apparatus of claim 12, wherein the backing plate includes selected one or more of: copper, silver, aluminum, graphene, gold, or brass.

16. The apparatus of claim 12, further comprising an epoxy coupled with a side of the backing plate.

17. The apparatus of claim 12, wherein the hole is dimensioned based upon a pattern of repelled electrons off the location of the semiconductor device.

18. A system comprising:
an electron source;
an apparatus that includes a semiconductor device, wherein the apparatus includes:
a cooling plate having a first side and a second side opposite the first side, wherein the cooling plate includes a manifold within the cooling plate;
a backing plate having a first side and a second side opposite the first side;
a cavity between the cooling plate and the backing plate, wherein the second side of the cooling plate and the first side of the backing plate are coupled to each other, wherein the coupling is an airtight coupling that completely surrounds the cavity, wherein the semiconductor device is within the cavity, and wherein the semiconductor device is thermally coupled with the cooling plate; and
a hole drilled from the first side of the cooling plate to the second side of the cooling plate, wherein the hole connects with a portion of the cavity, wherein the hole does not intersect the manifold, and wherein the hole exposes a portion of the semiconductor device; and
wherein the exposed portion of the semiconductor device and the electron source are aligned.

19. The system of claim 18, wherein at least a portion of the electron source, the hole, and the portion of the semiconductor device are under at least a partial vacuum.

20. The system of claim 18, further comprising a platform coupled to the apparatus, wherein the platform is configured to adjust the apparatus with respect to a location of the electron source.

21. The system of claim 18, further comprising automated test equipment (ATE), wherein the ATE is coupled with the electron source or the apparatus.

22. The system of claim 21, wherein the ATE is coupled with the electron source or the apparatus using cabling.

23. The system of claim 18, further comprising a cooling system, wherein the cooling system is thermally coupled with the manifold.

24. A method comprising:
providing an electron source for analysis of a semiconductor device;
providing an apparatus that includes the semiconductor device, wherein the apparatus includes:
a cooling plate having a first side and a second side opposite the first side, wherein the cooling plate includes a manifold within the cooling plate;
a backing plate having a first side and a second side opposite the first side;
a cavity between the cooling plate and the backing plate, wherein the second side of the cooling plate and the first side of the backing plate are coupled to each other, wherein the coupling forms an airtight coupling that completely surrounds the cavity, wherein the semiconductor device is within the cavity, and wherein the semiconductor device is thermally coupled with the cooling plate; and
a hole drilled from the first side of the cooling plate to the second side of the cooling plate, wherein the hole connects with a portion of the cavity, wherein the hole does not intersect the manifold, and wherein the hole exposes a portion of the semiconductor device; and
generating electrons from the electron source, wherein the generated electrons pass through the hole and are incident on a transistor layer or on a metal layer, and wherein secondary electrons are repelled off the exposed portion of the semiconductor device.

25. The method of claim 24, further comprising:
operating the semiconductor device;
collecting the repelled secondary electrons; and
analyzing an operation of the semiconductor device based on the collected repelled secondary electrons.
